(19) United States
(12) Patent Application Publication
(10) Pub. No.: US 2022/0186354 A1
(43) Pub. Date: Jun. 16, 2022

(54) SURFACE COATING TREATMENT

(71) Applicant: Lam Research Corporation, Fremont, CA (US)

(72) Inventors: Ann ERICKSON, Lake Oswego, OR (US); John DAUGHERTY, Fremont, CA (US); Robin KOSHY, Fremont, CA (US)

(21) Appl. No.: 17/600,031

(22) PCT Filed: Apr. 13, 2020
(86) PCT No.: PCT/US2020/027979

§ 371 Date: Sep. 29, 2021

Related U.S. Application Data
(60) Provisional application No. 62/834,835, filed on Apr. 16, 2019.

(51) Int. Cl. C23C 4/11; C23C 28/04; C25D 11/18; C23C 16/455; C23C 16/44

(52) U.S. Cl. CPC C23C 4/11; C23C 28/042; C23C 16/4404; C23C 16/45527; C25D 11/18

(57) ABSTRACT

A component for use as part of a plasma processing chamber is provided. The component has a component body adapted for use as part of a plasma processing chamber. A first ceramic coating of a ceramic material is on a surface of the component body, wherein the first ceramic coating has a first side adjacent to the component body and a second side spaced apart from the component body and wherein the first ceramic coating has a porosity and density. A second ceramic coating of the ceramic material is on the second side of the first ceramic coating, wherein the second ceramic coating has a porosity that is less than the porosity of the first ceramic coating and the second ceramic coating has a density that is greater than the density of the first ceramic coating.

### CROSS-REFERENCE TO RELATED APPLICATION

This application claims the benefit of priority of U.S. Application No. 62/834,835, filed Apr. 16, 2019, which is incorporated herein by reference for all purposes.

### BACKGROUND

The present disclosure relates to the manufacturing of semiconductor devices. More specifically, the disclosure relates to coating chamber surfaces used in manufacturing semiconductor devices.

During semiconductor wafer processing, plasma processing chambers are used to process semiconductor devices. Coatings are used to protect chamber surfaces.

For an electrostatic chuck (ESC) in a plasma processing chamber, plasma conditions cause erosion of the ESC or electrical arcing between the plasma and conductive components of the ESC. A protective coating may be applied to the surface of the ESC. Typically, the coefficient of thermal expansion (CTE) is greater for an aluminum ESC body than for a ceramic protective coating. A difference in CTE between an ESC body and protective coating may cause cracking of the protective coating.

### SUMMARY

To achieve the foregoing and in accordance with the purpose of the present disclosure, a component for use as part of a plasma processing chamber is provided. The component has a component body adapted for use as part of a plasma processing chamber. A first ceramic coating of a ceramic material is on a surface of the component body, wherein the first ceramic coating has a first side adjacent to the component body and a second side spaced apart from the component body and wherein the first ceramic coating has a porosity and density. A second ceramic coating of the ceramic material is on the second side of the first ceramic coating, wherein the second ceramic coating has a porosity that is less than the porosity of the first ceramic coating and the second ceramic coating has a density that is greater than the density of the first ceramic coating.

In another manifestation, a method for coating a component body for a part of a plasma processing chamber is provided. A first ceramic coating is formed on a surface of a component body, wherein the first ceramic coating has a first side adjacent to the component body and a second side spaced apart from the component body. The second side of the first ceramic coating is remelted to form a second ceramic coating on the first ceramic coating, wherein the second ceramic coating has a porosity that is less than a porosity of the first ceramic coating and the second ceramic coating has a density that is greater than a density of the first ceramic coating.

In another manifestation, a method for coating a component body for a part of a plasma processing chamber is provided. A first ceramic coating is sprayed on a surface of a component body, wherein the first ceramic coating has a first side adjacent to the component body and a second side spaced apart from the component body. A second ceramic coating is sprayed on the second side of the first ceramic coating, wherein the second ceramic coating has a porosity that is less than a porosity of the first ceramic coating and the second ceramic coating has a density that is greater than a density of the first ceramic coating, wherein spraying the second ceramic coating is at a direction more perpendicular to the surface of the component body than a direction of spraying of the first ceramic coating.

In another manifestation, a method for coating a component body of a part of a plasma processing chamber is provided. The component body is heated to a temperature above 200° C. A ceramic coating is formed on a surface of the component body, while the component body is heated to a temperature above 200° C.

In another manifestation, a component for part of a plasma processing chamber is provided. The component has a component body. An anodization layer is on a surface of the component body. An atomic layer deposition is on a surface of the anodization layer. A sprayed ceramic coating is on a surface of the atomic layer deposition.

In another manifestation, a method for coating an aluminum containing component body for part of a plasma processing chamber is provided. A surface of the component body is anodized to form an anodization layer, wherein a boehmite layer is formed on the anodization layer. The boehmite layer is removed. A ceramic coating is sprayed over the anodization layer.

In another manifestation, a component for use in a plasma processing chamber is provided. The component has a component body. A ceramic coating of a ceramic material is on a surface of the component body. Particles of a particle material are dispersed within the ceramic coating, wherein the particle material is less brittle than the ceramic material.

In another manifestation, a method for coating a component body of part of a plasma processing chamber is provided. A ceramic mixture of a first ceramic component and a second ceramic component is provided, wherein the first ceramic component has a lower melting point than second ceramic component. The ceramic mixture is thermal sprayed onto a plasma facing surface of component body, wherein the thermal spraying heats the ceramic mixture to a temperature that melts the first ceramic component, but does not melt the second ceramic component forming a first ceramic coating.

These and other features of the present disclosure will be described in more detail below in the detailed description of the disclosure and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a high level flow chart of an embodiment.

FIGS. 2A-B are schematic views of a substrate processed according to an embodiment.

FIG. 3 is a schematic view of a plasma processing system that may be used in an embodiment.

FIGS. 4A-B are schematic views of a substrate processed according to another embodiment.

FIG. 5 is a high level flow chart of another embodiment.

FIG. 6 is a schematic view of a substrate processed according to another embodiment.

FIG. 7 is a high level flow chart of another embodiment.

FIGS. 8A-B are schematic views of a substrate processed according to another embodiment.

FIG. 9 is a high level flow chart of another embodiment.

FIGS. 10A-E are schematic views of a substrate processed according to another embodiment.

### DETAILED DESCRIPTION OF THE PREFERRED EMBODIMENTS

The present disclosure will now be described in detail with reference to a few preferred embodiments thereof as illustrated in the accompanying drawings. In the following description, numerous specific details are set forth in order to provide a thorough understanding of the present disclosure. It will be apparent, however, to one skilled in the art, that the present disclosure may be practiced without some or all of these specific details. In other instances, well-known process steps and/or structures have not been described in detail in order to not unnecessarily obscure the present disclosure.

For an ESC in a plasma processing chamber, plasma conditions cause erosion of the ESC or electrical arcing between the plasma and conductive components of the ESC. A protective coating may be applied to the surface of the ESC. Typically, the coefficient of thermal expansion CTE is greater for an aluminum ESC body than for a ceramic protective coating. A difference in CTE between an ESC body and protective coating may cause cracking of the protective coating. Increasing porosity of the protective coating has been found to reduce cracking. However, increasing porosity also increases pathways for corrosive plasma and electrical arcing to reach and damage the ESC body.

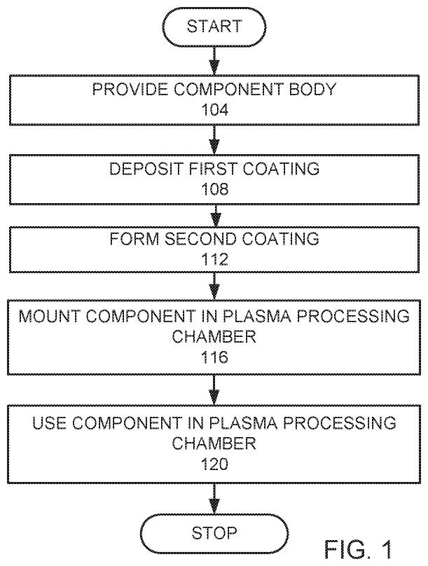

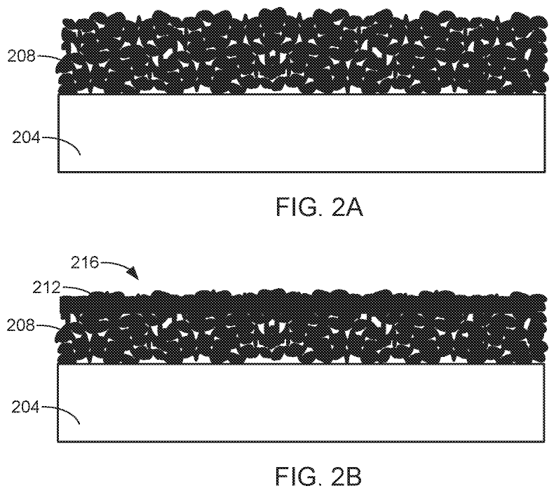

Several embodiments will be provided to provide an improved protective coating. To facilitate understanding of an embodiment, FIG. 1 is a high level flow chart of a process used in an embodiment of coating a component body. A component body is provided (step 104). In this example, the component body is made of aluminum with an anodized surface. A first ceramic coating of a ceramic material is applied on a surface of the component body (step 108). FIG. 2A is a schematic cross-sectional view of part of a component body 204 with a first ceramic coating 208 on a surface of the component body 204. The first ceramic coating 208 has a porosity. The porosity is indicated by the gaps between particles of the first ceramic coating 208. In this embodiment, the first ceramic coating 208 is deposited by a thermal spray deposition. In other embodiments, the first ceramic coating may be deposited by aerosol deposition. In this embodiment, the ceramic material is yttria or alumina. The component body 204 is on a first side of the first ceramic coating 208.

Thermal spraying is a general term used to describe a variety of coating processes, such as plasma spraying, arc spraying, flame/combustion spraying, and suspension spraying. All thermal spraying uses energy to heat a solid to a molten or plasticized state. The molten or plasticized material is accelerated towards the substrate so that the molten or plasticized material coats the surface of the substrate and then cools. These processes are distinct from vapor deposition processes. Vapor deposition processes use vaporized material instead of molten material. In this embodiment, the thickness of the ceramic coating is up to 1.5 mm. For example, the ceramic coating may have a thickness of between 0.1 mm to 1.5 mm. In another example, the ceramic coating may have a thickness between 0.3 to 1 mm Thinner ceramic coatings may not have problems with cracking.

A second ceramic coating of the ceramic material is formed on a second side of the first ceramic coating 208 of the ceramic material (step 112). In this embodiment, the second ceramic coating is formed by remelting the second side of the first ceramic coating 208. In this embodiment, the second surface of the first ceramic coating 208 is heated to cause the second side of the first ceramic coating 208 to melt. In this embodiment, a pulsed excimer laser provides localized heating of a region of the first ceramic coating 208. The region of the ceramic coating 208 is heated to a temperature that causes the second side of the first ceramic coating 208 to melt without melting lower levels of the first ceramic coating 208. In this embodiment, a laser beam is scanned over the second side of the first ceramic coating 208. In this embodiment, between 5% to 80% of the thickness of the first ceramic coating 208 is remelted. As a result, the thickness of the remaining first ceramic coating 208 to the thickness of the second ceramic coating is between 19:1 to 1:4. In other embodiments, between 50%-80% of the thickness of the first ceramic coating 208 is remelted. As a result, the thickness of the remaining first ceramic coating to the thickness of the second ceramic coating is between 1:1 to 1:4.

FIG. 2B is a schematic cross-sectional view of part of a component body 204 with a first ceramic coating 208 on a surface of the component body 204 after a second ceramic coating 212 has been formed on the second side of the first ceramic coating 208. The second ceramic coating is less porous than the first ceramic coating. The component body 204, first ceramic coating 208, and second ceramic coating 212 form a component 216. In this embodiment, the component 216 is an electrostatic chuck (ESC).

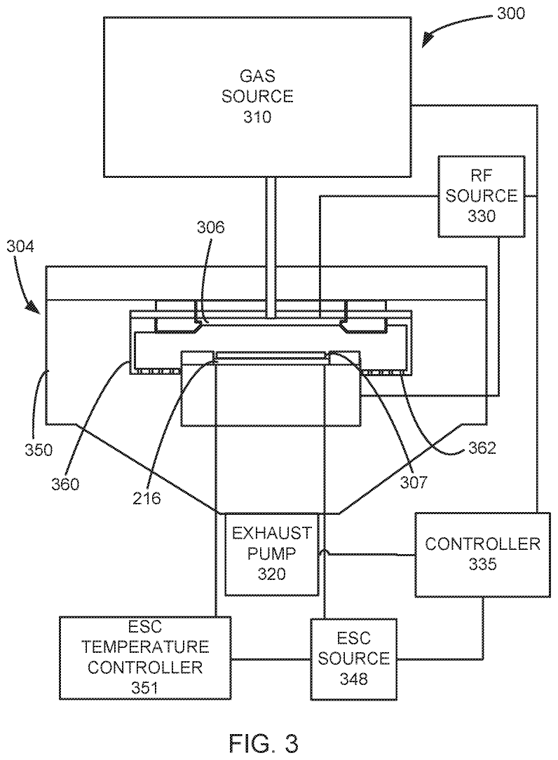

After the component is completed, the component 216 is mounted as part of a plasma processing chamber (step 116). FIG. 3 is a schematic view of a plasma processing system 300 for plasma processing substrates, in which the component 216 may be installed in an embodiment. In one or more embodiments, the plasma processing system 300 comprises a gas distribution plate 306 providing a gas inlet and the ESC component 216, within a plasma processing chamber 304, enclosed by a chamber wall 350. Within the plasma processing chamber 304, a substrate 307 is positioned on top of the ESC component 216. The ESC component 216 may provide a bias from an ESC power source 348. A gas source 310 is connected to the plasma processing chamber 304 through the gas distribution plate 306. An ESC temperature controller 351 is connected to the ESC component 216 and provides temperature control of the ESC component 216. A radio frequency (RF) power source 330 provides RF power to the ESC component 216 and an upper electrode. In this embodiment, the upper electrode is the gas distribution plate 306. In a preferred embodiment, 13.56 megahertz (MHz), 2 MHz, 60 MHz, and/or optionally, 27 MHz power sources make up the RF power source 330 and the ESC power source 348. A controller 335 is controllably connected to the RF power source 330, the ESC power source 348, an exhaust pump 320, and the gas source 310. A high flow liner 360 is a liner within the plasma processing chamber 304. The high flow liner 360 confines gas from the gas source and has slots 362. The slots 362 maintain a controlled flow of gas passing from the gas source 310 to the exhaust pump 320. An example of such a plasma processing chamber is the Flex® etch system manufactured by Lam Research Corporation of Fremont, Calif. The process chamber can be a CCP (capacitively coupled plasma) reactor or an ICP (inductively coupled plasma) reactor.

The plasma processing chamber 304 uses the component 216 to plasma process the substrate 307 (step 120). The plasma processing may be one or more processes of etching, depositing, passivating, or another plasma process. The plasma processing may also be performed in combination with nonplasma processing. Such processes may expose the ESC component 216 to plasmas containing halogen and/or oxygen.

Various components of the plasma processing chamber 304 use a metal base material coated with a dielectric material such as aluminum oxide or yttrium oxide deposited in a thermal or plasma spray process. Such components include ESC's 216, pinnacles, liners, gas distribution plates 306, among others. The first ceramic coating 208 and the second ceramic coating 212 may be over a plasma facing surface of the component body 204 to protect the component body 204 from plasma. In other embodiments, the ceramic material may comprise other metal oxides or metal oxyfluorides. Such ceramic material may comprise alumina, yttria, yttrium oxyfluoride, yttrium aluminum garnet (YAG), Yittria aluminum perovskite (YAP), Yittria aluminum monoclinic (YAM). In various embodiments the component body 204 may be aluminum containing

The integrity of the dielectric coating is crucial to maintain both electrical standoff and chemical resistance. However, many issues arise from this heterogeneous system. Higher thermal expansion of the metal can lead to cracking and delamination of the dielectric coating. Porosity in the coating may be required to accommodate some shape factors or to prevent cracking but can reduce dielectric standoff. Adhesion to the metal substrate can be sensitive to deposition conditions and surface quality. Residual stresses from the spray coating technique can lead to cracking or delamination over time, resulting in failure in the field. Any time the stresses exceed the material's ability to respond, failure can result.

A low-density coating has more room to absorb the shape change accompanying thermal expansion of the substrate, or to conform to more geometry changes without cracking. However, both the dielectric standoff and chemical resistance of a porous coating are diminished compared to a denser coating. This embodiment provides a porous first ceramic coating 208 on the metal component body 204 to allow more flexible conformation to the component body 204 and a denser second ceramic coating 212 to provide the dielectric stand-off or corrosion resistance that the part requires.

In this embodiment, the porosity of the first ceramic coating 208 is greater than 5%. The porosity of the second ceramic coating 212 is less than 1%. In another embodiment, the porosity of the first ceramic coating 208 is greater than 1%. The porosity of the second ceramic coating 212 is less than 0.5%. In various embodiments, the porosity of the second ceramic coating 212 is no more than 50% of the porosity of the first ceramic coating 208.

In various embodiments, the thickness of the first ceramic coating 208 is between 20 microns and 300 microns. The thickness of the second ceramic coating 212 is between 100 microns and 1500 microns.

In other embodiments, a rapid thermal processing (RTP) may be used to remelt a surface of the first ceramic coating 208. RTP provides heat that rapidly remelts a surface of the first ceramic coating 208. For example, a flashlamp may heat the entire or a large percentage of a surface of the first ceramic coating 208, to remelt the surface of the first ceramic coating 208 to form the second ceramic coating 212.

In another embodiment, after the first component body is provided (step 104), a first ceramic coating 208 is deposited on a surface of the first component body (step 108), using a thermal spray to deposit the first ceramic coating with a first porosity. A second ceramic coating is deposited on the first ceramic coating (step 112), using a thermal spray to deposit the second ceramic coating with a second porosity, wherein the first porosity is greater than the second porosity.

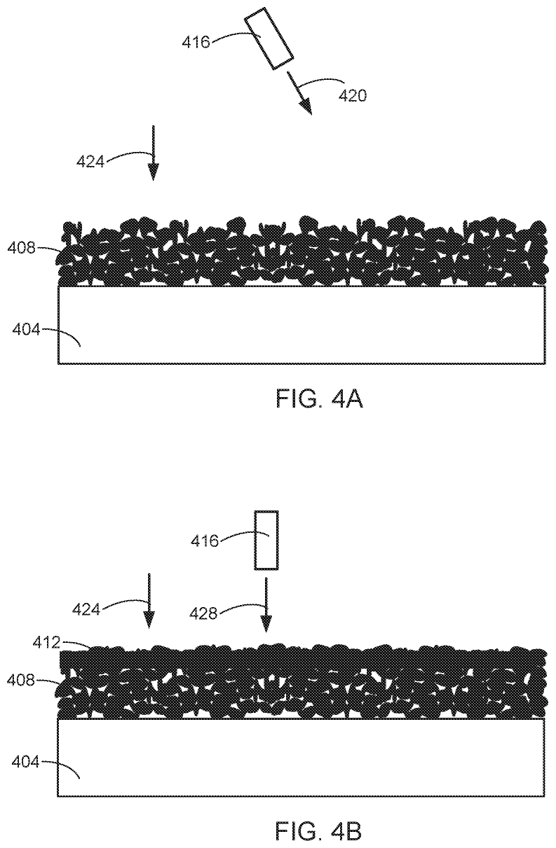

The spraying the second ceramic coating is at a direction more perpendicular to the surface of the component body than a direction of spraying of the first ceramic coating in order for the second ceramic coating to be less porous and more dense than the first ceramic coating. To facilitate understanding, FIG. 4A is a schematic cross-sectional view of part of a component body 404 with a first ceramic coating 408 on a surface of the component body 404. The first ceramic coating 408 is deposited by a sprayer 416 providing a spray with a spray direction 420. The spray direction 420 is different than a perpendicular direction 424 to the surface of the component body 404. FIG. 4B is a schematic cross-sectional view of part of a component body 404 with a first ceramic coating 408 on a surface of the component body 404 and a second ceramic coating 412 on a surface of the first ceramic coating 408. The second ceramic coating 412 is deposited by the sprayer 416 providing a spray with a spray direction 428. The spray direction 428 is in a perpendicular direction 424 to the surface of the component body 404.

It has been found that changing the angle of spray influences porosity and density of the spray coating. By spraying at an angle closer to perpendicular to the surface of the component the spray coating is denser and less porous. Therefore, by applying the first ceramic coating 408 at a first angle and then applying the second ceramic coating 412 at a second angle, where the second angle is closer to perpendicular than the first angle, the second ceramic coating 412 is less porous and denser than the first ceramic coating 408.

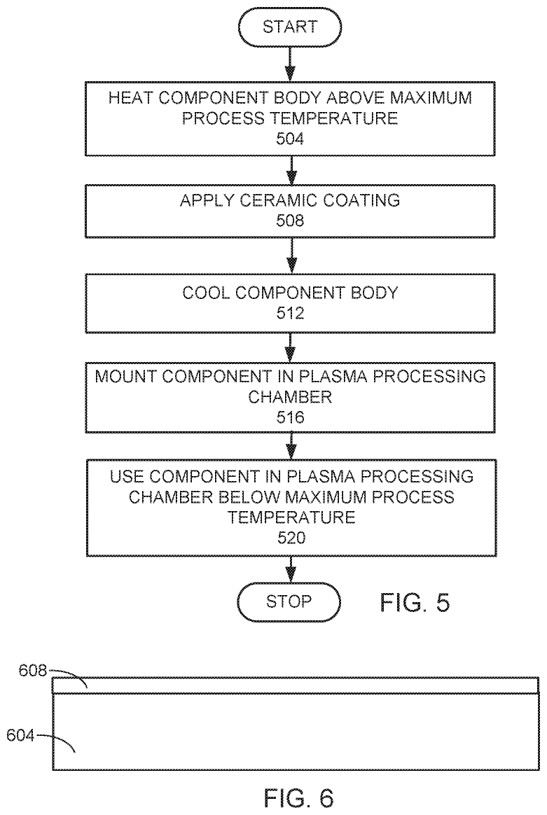

In another example, FIG. 5 is a high level flow chart of another embodiment. A component body is heated above a maximum process temperature (step 504). FIG. 6 is a schematic cross-sectional view of part of a component body 604. The maximum process temperature is the highest temperature a component would be heated to during plasma processing. A ceramic coating 608 is applied to the component body (step 508) at the temperature above the maximum process temperature.

Since applying the ceramic coating 608 at a temperature above the maximum process temperature, the use of the component in a processing chamber is at a temperature below the temperature used to apply the ceramic coating 608. As a result, during the use of the component in the processing chamber, the ceramic coating 608 is always under compressive stress. The compressive stress reduces cracking. This embodiment of applying the ceramic coating 608 at a temperature above the maximum process temperature may be combined with other embodiments. In one embodiment, the maximum processing temperature is 200° C. In such an embodiment, the component body is heated to a temperature of greater than 200° C.

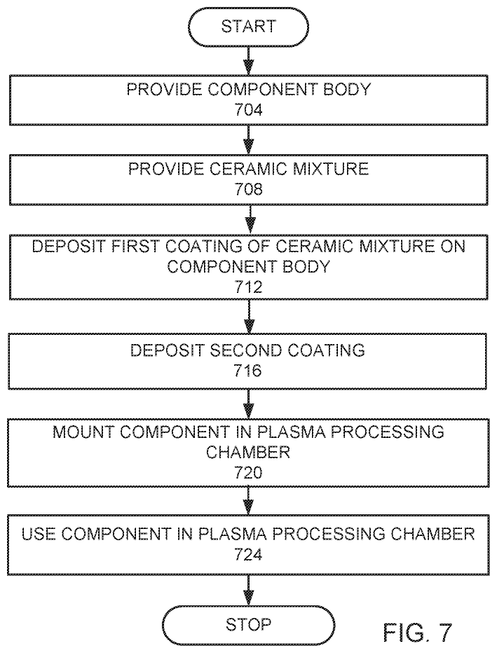

In another example, FIG. 7 is a high level flow chart of another embodiment. First, a component body is provided (step 704). In this embodiment, the component body is aluminum with an anodized surface. Next, a ceramic mixture is provided (step 708). The ceramic mixture is a mixture of two different ceramic materials. In this example, the ceramic mixture is yttria (Y₂O₃) powder and alumina (Al₂O₃) powder. Yttria has a melting point of 2410° C. Alumina has a melting point of 2040° C. In this embodiment, the percentage by volume of yttria in the alumina and yttria mixture is between 7.5% to 30%. This would mean that the ratio of alumina to yttria by volume would be between 1:11 to 3:7. A first coating of the ceramic mixture is deposited on the surface of the component body. In this example, a thermal spray is used that heats the ceramic mixture to a temperature between 2040° C. and 2410° C. In that temperature range, the alumina is melted and the yttria remains solid. The alumina is applied as a melted ceramic material and the yttria is applied as solid particles. The ceramic mixture has a first ceramic component of alumina and a second ceramic component of yttria.

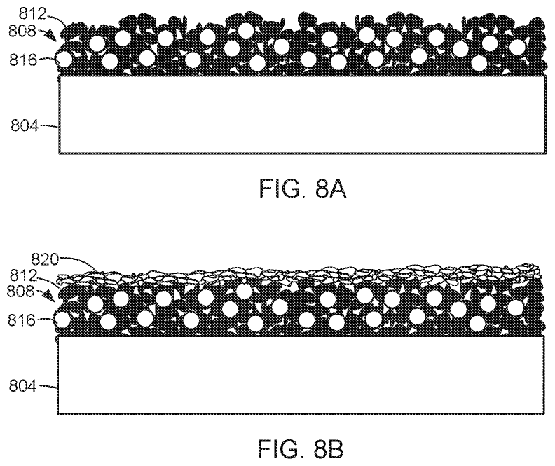

FIG. 8A is a schematic cross-sectional view of part of a component body 804 after the first coating 808 of the ceramic mixture has been deposited on the component body 804 (step 712). Since the first coating 808 is applied a temperature between the melting point of alumina and the melting point of yttria, the alumina is melted providing molten ceramic material, schematically illustrated as irregularly shaped melted alumina 812. Since the yttria is not melted the yttria is deposited as yttria particles 816, schematically illustrated as round particle material.

A second coating is deposited (step 716) over the first coating 808. In this example, the second coating is deposited by thermal spraying yttria at a temperature above 2410° C., so that the yttria is melted. FIG. 8B is a schematic cross-sectional view of the component body 804 after the second coating 820 of yttria has been deposited on the first coating 808 (step 716). The component is mounted in a plasma processing chamber (step 720). The component is used in the plasma processing chamber (step 724).

The denser and less porous a thermal spray coatings are more likely to crack. The reason for this is that denser and less porous coatings have increased stiffness and density, resulting in a higher elastic modulus and causing greater stress for a given thermal mismatch strain. The presence of pores may reduce cracking since the pores provide termination points for cracks. However, an increase in pores is not desirable, since more porous coatings provide reduced chemical and electrical protection. To provide benefits of more porous coatings and benefits of less porous coatings, the first coating 808 is deposited using a two-phase process of a melted material and a solid material. The solid material is a small fraction of the melted material. The yttria particles 816 are able to terminate cracks, without the need to increase porosity. The second coating 820 is able to have a low porosity with reduced cracking from thermal stress. Even though the second coating 816 has a lower porosity and therefore is more brittle, the first coating 808 arrests cracking due to thermal stress created by the component body 804 and reduces thermal stress on the second coating 820.

In other embodiments, the second coating 820 is not deposited. Instead, the first coating 808 is used as a protective layer, since the first coating 808 also has reduced porosity. In various embodiments, the ceramic mixture has a first component and a second component, where the first component has a lower melting point than the second component. The ceramic mixture has a ratio by volume of the first component to the second component in the range between 1:10 and 10:1. More specifically, the second component with the higher melting point is between 7.5% to 30% of the mixture of the first component and second component by volume. This would mean that the ratio of the second component to the first component by volume would be between 1:11 to 3:7.

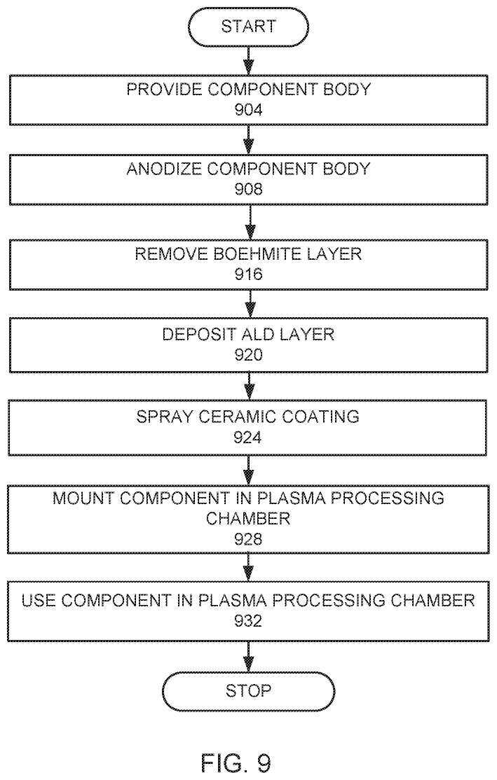

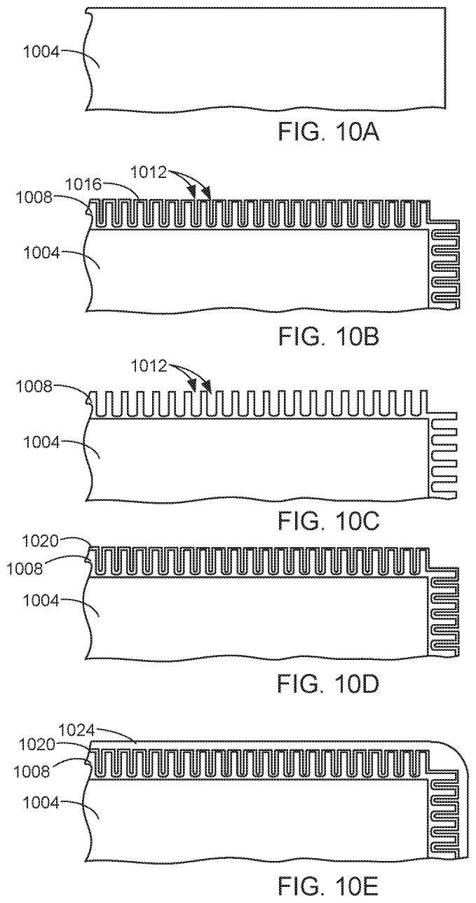

In another example, FIG. 9 is a high level flow chart of another embodiment. In this embodiment, a component body is provided (step 904), where the component body is aluminum. FIG. 10A is a schematic cross-sectional view of part of a component body 1004. Next, the component body 1004 is anodized (step 908). FIG. 10B is a schematic cross-sectional view of part of the component body 1004 after the surface of the component body 1004 has been anodized to form an anodization layer 1008. The anodization process forms pores 1012 in the anodization layer 1008. The pores 1012 may extend almost completely through the anodization layer 1008. In this embodiment, a boehmite layer 1016 is formed over the anodization layer 1008. The boehmite layer 1016 is an aluminum oxide hydroxide (y-AlO(OH)) mineral that may be formed during the anodization process.

Next, the boehmite layer 1016 is removed (step 916). In an embodiment, the boehmite layer 1016 is removed using physical bombardment, such as a bead blast. FIG. 10C is a schematic cross-sectional view of the component body 1004 after the boehmite layer 1016 is removed. Removing the boehmite layer 1016 (step 916) may also be used to condition the anodization layer 1008.

Next, an atomic layer deposition (ALD) layer is deposited on the anodization layer 1008 (step 920). In this embodiment, the ALD layer is a layer of aluminum oxide. FIG. 10D is a schematic cross-sectional view of the component body 1004 after the ALD layer 1020 has been deposited.

After the ALD layer 1020 is deposited, a ceramic coating is deposited on the ALD layer 1020 (step 924). In this embodiment, the ceramic coating is deposited by a thermal spray process. FIG. 10E is a schematic cross-sectional view of the component body 1004 after the ceramic coating 1024 has been deposited.

The boehmite layer 1016 is susceptible to attack by various gases. Therefore, to make the resulting protection less susceptible to attack by various gases the boehmite layer 1016 is removed. In addition, removing the boehmite layer 1016 increases the ability for subsequent depositions to better adhere to the anodization layer 1008. The ALD layer 1020 provides an additional protective layer that is conformal to the pores 1012.

In some embodiments, the boehmite layer 1016 is not removed. In some embodiments, the boehmite layer is not formed and therefore does not need to be removed. In other embodiments, the boehmite layer 1016 is removed, but the ALD layer 1020 is not deposited.

While this disclosure has been described in terms of several preferred embodiments, there are alterations, permutations, modifications, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure.

What is claimed is:

1. A component for use as part of a plasma processing chamber, comprising:
a component body adapted for use as part of the plasma processing chamber;
a first ceramic coating of a ceramic material on a surface of the component body, wherein the first ceramic coating has a first side adjacent to the component body and a second side spaced apart from the component body and wherein the first ceramic coating has a porosity and density; and
a second ceramic coating of the ceramic material on the second side of the first ceramic coating, wherein the second ceramic coating has a porosity that is less than the porosity of the first ceramic coating and the second ceramic coating has a density that is greater than the density of the first ceramic coating.

2. The component, as recited in claim 1, wherein the second ceramic coating is formed from remelting a surface of the first ceramic coating.

3. The component, as recited in claim 2, wherein 50% to 80% of a thickness of the first ceramic coating is remelted.

4. The component, as recited in claim 1, wherein the first ceramic coating and the second ceramic coating are spray coatings, wherein spraying the second ceramic coating sprays a denser second ceramic coating than the first ceramic coating.

5. The component, as recited in claim 1, wherein the first ceramic coating and the second ceramic coating are spray coatings, wherein spraying the second ceramic coating is at a direction more perpendicular to the surface of the component body than a direction of spraying of the first ceramic coating.

6. The component, as recited in claim 1, wherein the first ceramic coating has a thickness and the second ceramic coating has a thickness, wherein a ratio of the thickness of the first ceramic coating to the thickness of the second ceramic coating in a range between 19:1 to 1:4.

7. The component, as recited in claim 1, wherein the first ceramic coating and the second ceramic coating comprise at least one of a metal oxide or metal oxyfluoride.

8. The component, as recited in claim 1, wherein the first ceramic coating and the second ceramic coating comprise at least one of alumina or yttria.

9. The component, as recited in claim 1, wherein a porosity of the first ceramic coating is greater than 5% and wherein a porosity of the second ceramic coating is less than 1%.

10. A method for coating a component body for a part of a plasma processing chamber, comprising:
forming a first ceramic coating on a surface of a component body, wherein the first ceramic coating has a first side adjacent to the component body and a second side spaced apart from the component body; and
remelting the second side of the first ceramic coating to form a second ceramic coating on the first ceramic coating, wherein the second ceramic coating has a porosity that is less than a porosity of the first ceramic coating and the second ceramic coating has a density that is greater than a density of the first ceramic coating.

11. The method, as recited in claim 10, wherein 50% to 80% of a thickness of the first ceramic coating is remelted.

12. The method, as recited in claim 10, wherein the first ceramic coating and the second ceramic coating comprise at least one of a metal oxide or metal oxyfluoride.

13. The method, as recited in claim 10, wherein the first ceramic coating and the second ceramic coating comprise at least one of alumina or yttria.

14. The method, as recited in claim 10, wherein a porosity of the first ceramic coating is greater than 5% and wherein a porosity of the second ceramic coating is less than 1%.

15. A method for coating a component body for a part of a plasma processing chamber, comprising:
spraying a first ceramic coating on a surface of a component body, wherein the first ceramic coating has a first side adjacent to the component body and a second side spaced apart from the component body; and
spraying a second ceramic coating on the second side of the first ceramic coating, wherein the second ceramic coating has a porosity that is less than a porosity of the first ceramic coating and the second ceramic coating has a density that is greater than a density of the first ceramic coating, wherein spraying the second ceramic coating is at a direction more perpendicular to the surface of the component body than a direction of spraying of the first ceramic coating.

16. The method, as recited in claim 15, wherein 50% to 80% of a thickness of the first ceramic coating is remelted.

17. The method, as recited in claim 15, wherein the first ceramic coating and the second ceramic coating comprise a metal oxide or metal oxyfluoride.

18. The method, as recited in claim 15, wherein the first ceramic coating and the second ceramic coating comprise alumina or yttria.

19. The method, as recited in claim 15, wherein a porosity of the first ceramic coating is greater than 5% and wherein a porosity of the second ceramic coating is less than 1%.

20. A method for coating a component body of a part of a plasma processing chamber, comprising:
heating the component body to a temperature above 200° C.; and
forming a ceramic coating on a surface of the component body, while the component body is heated to a temperature above 200° C.

21. The method, as recited in claim 20, wherein the ceramic coating comprises at least on of a metal oxide or metal oxyfluoride.

22. The method, as recited in claim 20, wherein the ceramic coating comprises at least one of alumina or yttria.

23. A component for part of a plasma processing chamber, comprising:
a component body;
an anodization layer on a surface of the component body;
an atomic layer deposition on a surface of the anodization layer; and
a sprayed ceramic coating on a surface of the atomic layer deposition.

24. The component, as recited in claim 23, wherein the component body is aluminum.

25. The component, as recited in claim 23, wherein the sprayed ceramic coating comprises at least one of a metal oxide or metal oxyfluoride.

26. The component, as recited in claim 23, wherein the sprayed ceramic coating comprises at least one of alumina or yttria.

27. A method for coating an aluminum containing component body for part of a plasma processing chamber, comprising:
anodizing a surface of the component body to form an anodization layer, wherein a boehmite layer is formed on the anodization layer;
removing the boehmite layer; and
spraying a ceramic coating over the anodization layer.

28. The method, as recited in claim 27, wherein the ceramic coating comprises at least one of metal oxide or metal oxyfluoride.

29. The method, as recited in claim 27, wherein the ceramic coating comprises at least one of alumina or yttria.

30. The method, as recited in claim 27, further comprising forming an atomic layer deposition on the anodization layer before spraying the ceramic coating.

31. A component for use in a plasma processing chamber, comprising:
a component body;
a ceramic coating of a ceramic material on a surface of the component body; and
particles of a particle material dispersed within the ceramic coating, wherein the particle material is less brittle than the ceramic material.

32. The component, as recited in claim 31, wherein the particle material has a higher melting point than a melting point of the ceramic material.

33. The component, as recited in claim 31, wherein a ratio of particle material to the ceramic material is between 1:11 to 3:7 by volume.

34. The component, as recited in claim 31, wherein the ceramic material is applied as melted ceramic material and the particles are applied as solid particles.

35. The component, as recited in claim 31, further comprising a particle coating of the particle material over the ceramic coating of the ceramic material.

36. The component, as recited in claim 31, wherein the ceramic material and the particle material each comprise at least one of a metal oxide or metal oxyfluoride.

37. The component, as recited in claim 31, wherein the ceramic material comprises alumina and the particle material comprises yttria.

38. A method for coating a component body of part of a plasma processing chamber, comprising:
providing a ceramic mixture of a first ceramic component and a second ceramic component, wherein the first ceramic component has a lower melting point than second ceramic component; and
thermal spraying the ceramic mixture onto a plasma facing surface of component body, wherein the thermal spraying heats the ceramic mixture to a temperature that melts the first ceramic component, but does not melt the second ceramic component forming a first ceramic coating.

39. The method, as recited in claim 38, further comprising thermal spraying a powder of the second ceramic component on the first ceramic coating, wherein the powder of the second ceramic component is heated to a temperature that melts the second ceramic component.

40. The method, as recited in claim 38, wherein the first ceramic component is alumina and wherein the second ceramic component is yttria.
